(19) United States
(12) Patent Application Publication
(10) Pub. No.: US 2022/0108733 A1
(43) Pub. Date: Apr. 7, 2022

(54) Memory Circuits And Methods With Write Assist

(71) Applicant: Intel Corporation, Santa Clara, CA (US)

(72) Inventors: Wayson Lowe, Redwood City, CA (US); Ban Wong, Milpitas, CA (US)

(73) Assignee: Intel Corporation, Santa Clara, CA (US)

(21) Appl. No.: 17/553,439

(22) Filed: Dec. 16, 2021

(51) Int. Cl. G11C 7/10; G11C 7/12; G11C 8/10; G11C 7/22; G11C 11/419

(52) U.S. Cl. CPC G11C 7/1096; G11C 7/12; G11C 11/419; G11C 7/22; G11C 8/10

(57) ABSTRACT

A memory circuit includes a column of memory cells. A column selection circuit is coupled to the column of the memory cells through a bit line. The column selection circuit pulls a voltage of the bit line toward a predefined voltage in response to a write control signal during a write operation to at least one of the memory cells in the column of the memory cells. A write enable circuit generates a write enable signal. A regenerative repeater circuit is coupled to the column of the memory cells through the bit line. The regenerative repeater circuit pulls the voltage of the bit line toward the predefined voltage in response to the write enable signal during the write operation.

### FIELD OF THE DISCLOSURE

The present disclosure relates to electronic circuits, and more particularly, to memory circuits and methods with write assist.

### STATEMENT OF GOVERNMENT INTEREST

This invention was made with government support under agreement number HR0011-21-3-0001 awarded by DARPA. The government has certain rights in the invention.

### BACKGROUND

Many types of integrated circuits (ICs) have memory circuits that include arrays of memory cells. Each of the memory cells stores one or more digital bits. The memory cells in a memory array are typically arranged in rows and columns. The memory cells may be, for example, random access memory (RAM), such as static RAM (SRAM) or dynamic RAM (DRAM).

### BRIEF DESCRIPTION OF THE DRAWINGS

FIG. 1 illustrates an example of a memory circuit that includes regenerative repeater circuits.

FIG. 2 illustrates an example of the regenerative repeater circuits of FIG. 1.

FIG. 3 illustrates an example of a memory circuit that includes a memory array circuit having memory cells and a timing column of dummy timing circuits.

FIG. 4A illustrates an example of a memory circuit that can be used as each of the memory cells in the memory array circuit of FIG. 1 and/or in the memory array circuit of FIG. 3.

FIG. 4B illustrates an example of a timing circuit that can be used as each of the timing circuits in the timing column of timing circuits in the memory array circuit of FIG. 3.

FIG. 5 is a timing diagram that illustrates examples of waveforms for 10 of the signals in the memory circuit shown in FIG. 3.

FIG. 6 illustrates a programmable logic integrated circuit (IC) that includes at least one of the memory circuits of FIGS. 1 and 3.

### DETAILED DESCRIPTION

Each row of memory cells in a memory array may, for example, be controlled by a word line, and each column of the memory cells in the memory array may, for example, be controlled by one or more bit lines. In modern semiconductor process nodes that are less than 14 nanometer (nm), the bit line is highly resistive due to the narrow width of the bit line and the small grain size of the metal (e.g., copper) that is used to form the bit line. The interconnect resistance of the bit line is high because the copper core of the bit line is narrow, the barrier material around the copper core is a high resistivity material, and the barrier thickness does not scale. The grain size of the metal is limited by the narrow trench of the bit line. The grain size of the metal in the bit line is smaller than the mean free path of the carriers, which causes grain boundary scattering that further increases the resistance of the bit line. The resistivity of the bit lines in memory arrays continues to increase exponentially at progressively smaller semiconductor process nodes that are less than 14 nm.

In addition, the interconnect width of bit lines in memory circuits is reduced in smaller process nodes to enable scaling of the area of each memory cell. As the width of the bit lines are decreased, the timing constant of the bit lines increases, which makes it more difficult to write to the memory cells in the farthest end of the memory circuit from the write driver. This effect limits the number of rows of memory cells in the memory array in order to meet the required performance and writability. The limit on the number of rows of memory cells reduces the efficiency of the memory array and increases the area of the memory circuit.

According to some examples disclosed herein, a memory circuit includes an array of memory cells, word line decoder circuits, bit line select circuits, a write driver circuit, and a regenerative repeater circuit. The word line decoder circuits control word lines that are coupled to rows of the memory cells. The bit line select circuits control bit lines that are coupled to columns of the memory cells. The regenerative repeater circuit is coupled to the bit lines. The regenerative repeater circuit is a write assist circuit that speeds up the process of writing bits to the memory cells. The regenerative repeater circuit enables robust write operations in memory circuits that are in the worst-case process and interconnect corners within a bin of memory circuits. The regenerative repeater circuit can provide write assist during a write operation to the memory cells, including the memory cell farthest from the write driver circuit. In some implementations, the regenerative repeater circuit can obviate the need for other write assist circuits to reduce write dynamic power (e.g., by 25%) and circuit area (e.g., by 15%).

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices. The term “circuit” may mean one or more passive and/or active electrical components that are arranged to cooperate with one another to provide a desired function.

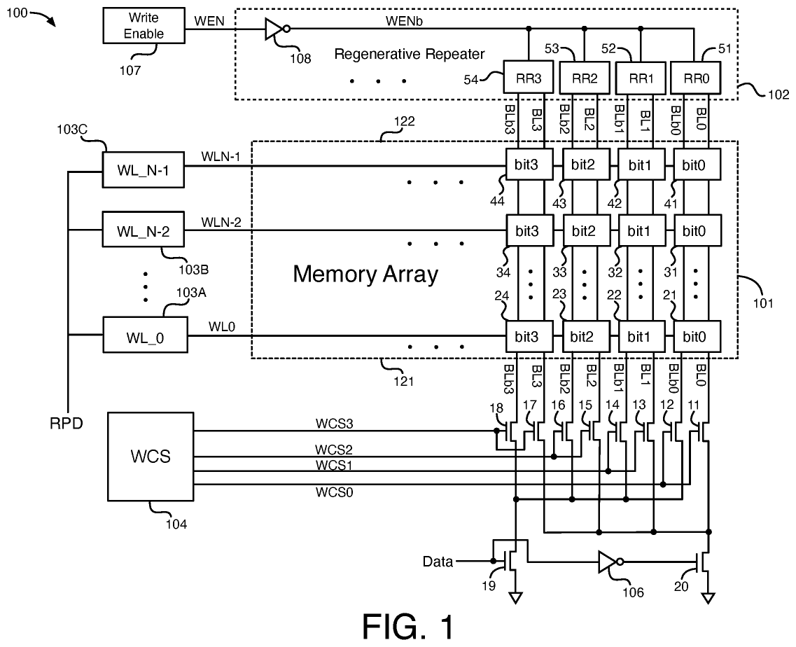

FIG. 1 illustrates an example of a memory circuit 100 that includes regenerative repeater circuits. Memory circuit 100 of Figure (FIG. 1 includes a memory array circuit 101 having an N number of rows of memory cells, regenerative repeater circuit block 102, an N number of word line (WL) decoder circuits 103 (including word line decoder circuits 103A-103C), write column select (WCS) circuit 104, n-channel field-effect transistors (FETs) 11-20, inverter circuit 106, and write enable circuit 107. N may be any integer number. Each of the N rows of memory cells in array 101 includes an M number of memory cells in an M number of columns. M may be any integer number. Four memory cells (bit0, bit1, bit2, bit3) are shown in three rows in FIG. 1 as an example that is not intended to be limiting. In the example of FIG. 1, row 0 includes memory cells 21-24, row N-2 includes memory cells 31-34, and row N-1 includes memory cells 41-44.

Memory circuit 100 may be in an integrated circuit (IC) die. The IC may be any type of IC, such as a programmable integrated circuit (IC), a microprocessor, a graphics processing unit, an application specific IC, a memory IC, etc. Programmable ICs include any integrated circuits that may be programmed to perform desired functions, including programmable logic arrays (PLAs), programmable array logic (PAL), field programmable gate arrays (FPGAs), and programmable logic devices (PLDs). The memory cells in array 101 may be any type of memory circuit, such as a static random access memory (SRAM), a dynamic RAM (DRAM), or a non-volatile memory circuit.

Row pre-decoder signals RPD are provided to inputs of WL decoder circuits 103. The RPD signals determine which of the word lines in memory array 101 are selected to perform a write operation. WL decoder circuits 103A, . . . 103B, 103C decode the RPD signals to generate an N number of decoded word line signals WL0, . . . WLN-2, WLN-1 on the word lines for rows 0, . . . N-2, N-1, respectively, of the memory cells. The word lines for the rows 0, . . . N-2, N-1 are coupled to the M memory cells in the respective rows. For example, the decoded word line signals WL0, . . . WLN-2, WLN-1 are transmitted to the memory cells 21-24, . . . 31-34, 41-44 in rows 0, . . . N-2, N-1, respectively. WL decoder circuits 103 assert the word line signals on the word lines that are indicated by the row pre-decoder signals RPD to high voltages.

The write column select (WCS) circuit 104 generates an M number of write control signals. One of the write control signals is generated for each of the columns of the memory cells in memory array 101. For example, WCS circuit 104 generates write control signals WCS0, WCS1, WCS2, and WCS3 for columns 0, 1, 2, and 3, respectively, of the memory cells. Each of the write control signals generated by circuit 104 is provided to the gates of two n-channel transistors that are coupled to bits lines for one of the columns of the memory cells in memory array circuit 101. For example, write control signals WCS0, WCS1, WCS2, and WCS3 are provided to the gates of n-channel transistors 11-12, 13-14, 15-16, and 17-18, respectively, as shown in FIG. 1.

The drains of transistors 11, 12, 13, 14, 15, 16, 17, and 18 are coupled to the bit lines that transmit bit line signals BL0, BLb0, BL1, BLb1, BL2, BLb2, BL3, and BLb3, respectively. Transistors 11-18 are coupled to the lower ends of these bit lines in FIG. 1. WCS circuit 104 and transistors 11-18 are a column selection circuit that is coupled to the bit lines next to a first edge 121 of the memory array 101. The bit lines that transmit bit line signals BL0 and BLb0 are coupled to the memory cells in column 0, including memory cells 21, 31, and 41. The bit lines that transmit bit line signals BL1 and BLb 1 are coupled to the memory cells in column 1, including memory cells 22, 32, and 42. The bit lines that transmit bit line signals BL2 and BLb2 are coupled to the memory cells in column 2, including memory cells 23, 33, and 43. The bit lines that transmit bit line signals BL3 and BLb3 are coupled to the memory cells in column 3, including memory cells 24, 34, and 44.

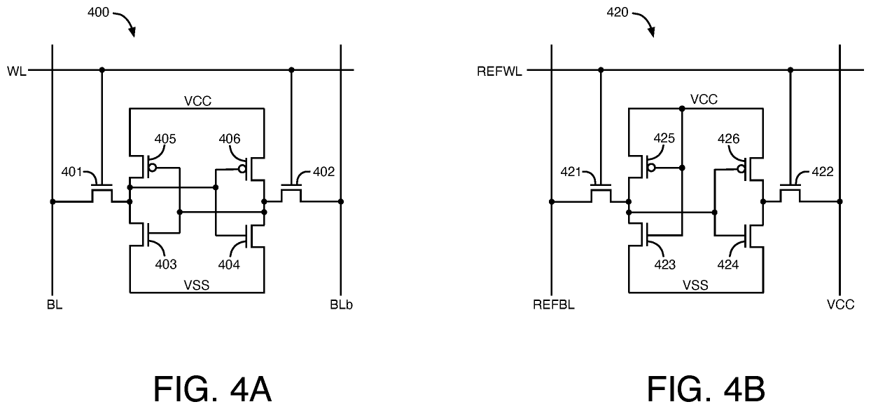

Each pair of the bit lines transmits a non-inverted bit line signal and an inverted bit line signal. For example, bit line signals BLb0, BLb1, BLb2, and BLb3 have logically inverted states relative to bit line signals BL0, BL1, BL2, and BL3, respectively. WCS circuit 104 sets the voltages of the write control signals, including signals WCS0-WCS3, to control the voltages of the bit line signals, including bit line signals BL0-BLb3, during a write operation. In response to the word line and the bit lines that are coupled to a memory cell being asserted to predefined voltages, a write operation is performed in that memory cell, as described in further detail below with respect to the example of FIG. 4A.

The sources of transistors 11, 13, 15, and 17 are coupled to the drain of n-channel transistor 20. The sources of transistors 12, 14, 16, and 18 are coupled to the drain of n-channel transistor 19. A Data input signal is provided to the gate of transistor 19 and to an input of inverter circuit 106. Inverter circuit 106 inverts the Data input signal to generate an inverted Data signal that is provided to the gate of transistor 20. The sources of transistors 19-20 are coupled to the ground voltage. Transistors 19-20 function as a write driver circuit that controls writing bits to the memory cells.

Regenerative repeater circuit block 102 includes an inverter circuit 108 and an M number of regenerative repeater circuits, such as regenerative repeater circuits 51, 52, 53, and 54, as shown in FIG. 1. Each of the regenerative repeater circuits in regenerative repeater circuit block 102 is coupled to one of the columns of memory cells in memory array circuit 101. Each of the regenerative repeater circuits in regenerative repeater circuit block 102 is coupled to the upper ends of the bit lines that are coupled to one of the columns of the memory cells in memory array circuit 101. For example, regenerative repeater circuits 51, 52, 53, and 54 are coupled to the pairs of bit lines that are coupled to memory cells 21/31/41, 22/32/42, 23/33/43, and 24/34/44 in columns 0, 1, 2, and 3, respectively. Regenerative repeater circuits 51, 52, 53, and 54 are coupled to the bit lines that transmit bit line signals BL0-BLb0, BL1-BLb1, BL2-BLb2, and BL3-BLb3, respectively, at the upper ends of these bit lines in FIG. 1. The regenerative repeater circuits 51, 52, 53, and 54 in block 102 are next to a second edge 122 of memory array 101 that is opposite to the first edge 121.

Regenerative repeater circuit block 102 increases the speed of write operations to the memory cells in memory array circuit 101. The regenerative repeater circuit block 102 enables robust write operations to the memory cells in memory array circuit 101 even if memory circuit 100 is in a worst-case process and/or interconnect corner. As an example, each of the regenerative repeater circuits in regenerative repeater circuit block 102 may increase the speed of a write operation by drawing current from (or providing current to) one of the bit lines coupled to one of the columns of memory cells in memory array circuit 101. Regenerative repeater circuit block 102 can enable robust write operations despite the high resistivity of the bit lines without reducing performance and efficiency of the memory array circuit 101 and without increasing the size of the memory circuit 100.

The write enable circuit 107 generates a write enable signal WEN that is driven to a low voltage to enable the regenerative repeater circuits in regenerative repeater circuit block 102 during a write operation. Inverter circuit 108 inverts the write enable signal WEN to generate an inverted write enable signal WENb. Signal WENb is provided to an input of each of the regenerative repeater circuits, including regenerative repeater circuits 51-54.

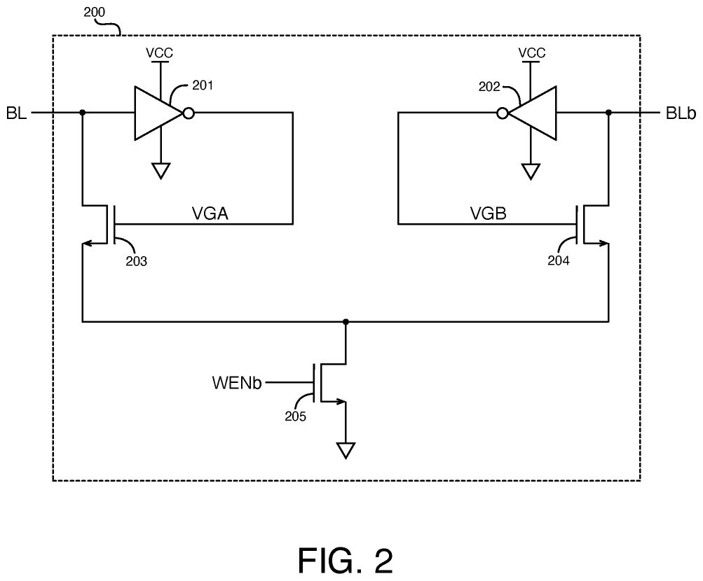

FIG. 2 illustrates an example of a regenerative repeater circuit 200. Regenerative repeater circuit 200 of FIG. 2 is an example of each of the regenerative repeater circuits in the regenerative repeater circuit block 102 of FIG. 1. For example, each of the regenerative repeater circuits 51-54 may include an instance of the regenerative repeater circuit 200. In the example of FIG. 2, regenerative repeater circuit 200 includes inverter circuits 201-202 and n-channel field-effect transistors 203-205. Each of the inverter circuits 201-202 is coupled between a supply terminal at supply voltage VCC and a terminal at the ground voltage. The input of inverter circuit 201 and the drain of transistor 203 are coupled to a first bit line BL. The input of inverter circuit 202 and the drain of transistor 204 are coupled to a second bit line BLb. The output of inverter circuit 201 is coupled to the gate of transistor 203. The output of inverter circuit 202 is coupled to the gate of transistor 204. The sources of transistors 203-204 are coupled to the drain of transistor 205. The source of transistor 205 is coupled to the ground voltage. The gate of transistor 205 is coupled to receive the inverted write enable signal WENb from inverter 108.

Bit lines BL and BLb are a pair of bit lines that are coupled to a column of memory cells in memory array circuit 101. Bit line BL transmits a non-inverted bit line signal, and bit line BLb transmits an inverted bit line signal. As examples, bit lines BL and BLb may transmit bit line signals BL0 and BLb0, BL1 and BLb 1, BL2 and BLb2, or BL3 and BLb3.

Details of a write operation are now described in the context of the circuits shown in FIGS. 1 and 2. During a write operation to write data to one or more of the memory cells in memory array circuit 101, WL decoder circuits 103A, . . . 103B, 103C assert the word line signals WL0, . . . WLN-2, WLN-1 on one or more of the word lines for the rows 0, . . . N-2, N-1, respectively, of memory cells that are indicated by the row pre-decoder signals RPD. In addition, WCS circuit 104 asserts the write control signals for the columns of memory cells that are selected to be written to during the write operation. For example, WCS circuit 104 may assert one or more of signals WCS0, WCS1, WCS2, and/or WCS3 to select columns 0, 1, 2, and/or 3, respectively, of the memory cells. As a more specific example, WCS circuit 104 may drive one or more of signals WCS0, WCS1, WCS2, and/or WCS3 to high voltages to turn on transistors 11-12, 13-14, 15-16, and/or 17-18 to enable bits to be written to the memory cells in the selected columns 0, 1, 2, and/or 3, respectively, through the bit lines. WCS circuit 104 and transistors 11-18 are a bit line selection circuit.

During a write operation, the Data input signal is driven to a low voltage to write a logic low bit (i.e., a 0 bit) to the memory cells that are in the columns selected by the asserted write control signals generated by WCS circuit 104 and in the rows selected by the asserted word line signals generated by WL decoder circuits 103. In response to the Data input signal having a low voltage, transistor 19 is off, and transistor 20 is on. When transistor 19 is off in response to the Data input signal being low, the transistors (e.g., transistors 12, 14, 16, and 18) coupled to the bit lines transmitting the inverted bit line signals (e.g., BLb0, BLb 1, BLb2, BLb3) are decoupled from ground. When transistor 20 is on in response to the inverted Data input signal being high, the transistors (e.g., transistors 11, 13, 15, and 17) coupled to the bit lines transmitting the non-inverted bit line signals (e.g., BL0, BL1, BL2, BL3) are coupled to ground. As a result, transistor 20 discharges the non-inverted bit line signals on bit lines selected by the asserted write control signals to the ground voltage. For example, if transistors 11, 13, 15, and 17 are on, then these transistors and transistor 20 discharge bit line signals BL0, BL1, BL2, and BL3 to the ground voltage.

Write enable circuit 107 drives the write enable signal WEN to a low voltage during a write operation. In response to the write enable signal WEN being low, inverter circuit 108 drives the inverted write enable signal WENb to a high voltage. Transistor 205 in regenerative repeater circuit 200 of FIG. 2 is on in response to the inverted write enable signal WENb being high.

Referring to FIG. 2, in response to transistor 20 discharging the non-inverted bit line BL to ground to write a 0 bit to one or more memory cells that are coupled to bit lines BL and BLb, the voltage on bit line BL decreases below a voltage that causes inverter circuit 201 to increase the gate voltage VGA of transistor 203 above its threshold voltage, turning transistor 203 on. When transistor 203 is on, transistors 203 and 205 create a current path from bit line BL to ground that discharges bit line BL. Current flow from bit line BL through transistors 203 and 205 to ground speeds up the discharge rate of bit line BL during the write operation, even if bit line BL has a high interconnect resistivity. Because bit line BLb is decoupled from ground by transistor 19 when the Data signal is low, inverter circuit 202 keeps transistor 204 off. The voltage difference between the bit lines BL and BLb causes a 0 bit to be written to the memory cells that are coupled to bit lines BL and BLb and that are selected by the asserted word line signals during the write operation.

During a write operation, the Data input signal is driven to a high voltage to write a logic high bit (i.e., a 1 bit) to the memory cells that are in the columns selected by the asserted write control signals generated by WCS circuit 104 and in the rows selected by the asserted word line signals generated by WL decoder circuits 103. When transistor 20 is off in response to the inverted Data signal having a low voltage, the transistors (e.g., transistors 11, 13, 15, and 17) coupled to the bit lines transmitting the non-inverted bit line signals (e.g., BL0, BL1, BL2, BL3) are decoupled from ground. When transistor 19 is on in response to the input Data signal having a high voltage, the transistors (e.g., transistors 12, 14, 16, and 18) coupled to the bit lines transmitting the inverted bit line signals (e.g., BLb0, BLb1, BLb2, BLb3) are coupled to ground. As a result, transistor 19 discharges the inverted bit line signals on the bit lines selected by the asserted write control signals to the ground voltage. For example, if transistors 12, 14, 16, and 18 are on, then these transistors and transistor 19 discharge bit line signals BLb0, BLb 1, BLb2, and BLb3 to the ground voltage.

Referring to FIG. 2, in response to transistor 19 being on to discharge the inverted bit line BLb to ground to write a 1 bit to one or more memory cells that are coupled to bit lines BL and BLb, the voltage on bit line BLb decreases below a voltage that causes inverter circuit 202 to increase the gate voltage VGB of transistor 204 above its threshold voltage, turning transistor 204 on. When transistor 204 is on, transistors 204 and 205 create a current path from bit line BLb to ground, and as a result, current flows from bit line BLb to ground through transistors 204 and 205. The current flow through transistors 204 and 205 speeds up the discharge rate of bit line BLb during the write operation, even if bit line BLb has a high interconnect resistivity. Because bit line BL is decoupled from ground by transistor 20 when the inverted Data signal is low, inverter circuit 201 keeps transistor 203 off. The voltage difference between the bit lines BL and BLb causes a 1 bit to be written to the memory cells that are coupled to bit lines BL and BLb and that are selected by the asserted word line signals during the write operation.

As an example that is not intended to be limiting, the discharge time for the voltage on the bit line BL or BLb to decrease from supply voltage VCC to ½ supply voltage VCC may be 0.75 of a resistor-capacitor (RC) time constant t, where t=R*C. The discharge time for the voltage on the bit line BL or BLb to decrease from ½ supply voltage VCC to the voltage level to write a 0 or 1 bit to one of the memory cells may be about 4.25 multiplied by the time constant t (i.e., 4.25*t). The regenerative repeater circuit 200 of FIG. 2 can reduce the discharge time to about 1 time constant t for a bit line to discharge from ½ VCC to the voltage level to write a 0 or 1 bit to a memory cell. As the resistance of the bit line increases, the time constant t also increases. Regenerative repeater circuit 200 can provide a significant reduction in the time needed to discharge one of the bit lines BL or BLb during a write operation from about 5 t to about 1.75 t.

According to other examples disclosed herein, a memory circuit includes an array of memory cells, word line decoder circuits, a bit line selection circuit, a write driver circuit, and a write assist circuit. The word line decoder circuits control word lines that are coupled to rows of the memory cells. The bit line selection circuit controls bit lines that are coupled to columns of the memory cells. The write assist circuit assists the array in writing bits to the memory cells during write operations. The array of memory cells also includes a timing column of dummy timing circuits. The dummy timing circuits speed up the process of writing bits to the memory cells during write operations. The dummy timing circuits enable robust write operations in memory circuits that are in the worst-case process and interconnect corners within a bin of integrated circuit dies.

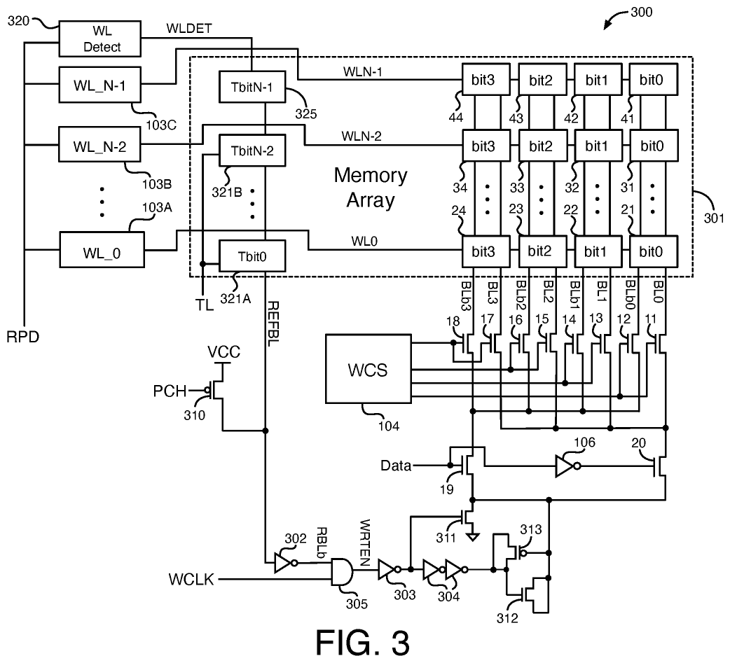

FIG. 3 illustrates an example of a memory circuit 300 that includes a memory array circuit having memory cells and a timing column of timing circuits. Memory circuit 300 of Figure (FIG. 3 includes a memory array circuit 301, an N number of word line (WL) decoder circuits 103 (including word line decoder circuits 103A-103C), write column select circuit 104, n-channel field-effect transistors (FETs) 11-20 and 311-312, inverter circuit 106, p-channel FETs 310 and 313, inverter circuits 302-304, AND gate circuit 305, and word line (WL) detect circuit 320. Memory circuit 300 may be in an integrated circuit (IC) die. The IC may be any type of IC, such as a programmable integrated circuit (IC), a microprocessor, a graphics processing unit, an application specific IC, a memory IC, etc.

The WL decoder circuits 103, write column select circuit 104, inverter 106, and transistors 11-20 function as disclosed herein with respect to FIG. 1. Memory array circuit 301 has an N number of rows of memory cells, including memory cells 21-24, 31-34, and 41-44. N may be any integer number. Each of the N rows of memory cells in array 301 includes an M number of memory cells in an M number of columns. M may be any integer number. Four memory cells (bit0, bit1, bit2, bit3) are shown in three rows in FIG. 3 as an example that is not intended to be limiting. Each of the memory cells in memory array 301 is coupled to a non-inverted bit line, an inverted bit line, and a word line, as shown in FIG. 3, and as described herein with respect to FIG. 1. A bit can be written to any of the memory cells in memory array 301 by grounding one of the 2 bit lines coupled to the memory cell and asserting the word line coupled to the memory cell, as disclosed herein with respect to FIG. 1.

Memory array circuit 301 also has a timing column of dummy timing circuits 321, including dummy timing circuit 321A in row 0 and dummy timing circuit 321B in row N-2, and timing circuit 325 in row N-1. The timing column has a timing circuit in each of the rows of memory cells in array 301. Timing circuit 325 is coupled to receive the output signal WLDET of WL detect circuit 320. Timing circuits 321 and 325 are not coupled to receive any of the decoded word line signals generated by circuits 103.

Each of the dummy timing circuits 321 is coupled to receive a tie low signal TL (e.g., at the ground voltage). Each of the timing circuits 321 and 325 is coupled to a conductive line that provides a reference bit line signal REFBL. P-channel transistor 310 is coupled between a supply voltage VCC and the conductive line that provides signal REFBL. The gate of transistor 310 is coupled to receive a pre-charge signal PCH. The conductive line that provides signal REFBL is also coupled to an input of inverter circuit 302. A write clock signal WCLK and the output signal RBLb of inverter circuit 302 are provided to inputs of AND gate circuit 305. The output signal WRTEN of AND gate circuit 305 is provided to an input of inverter circuit 303. Inverter circuit 303 inverts the WRTEN output signal of AND gate circuit 305 to generate an inverted signal that is provided to the gate of transistor 311 and to an input of inverter circuits 304. Inverter circuits 304 include 2 inverter circuits coupled in series. Inverter circuits 304 buffer the output signal of inverter circuit 303 to generate a buffered signal that is provided to terminals of transistors 312-313. The terminals of transistors 312-313 are coupled to form 2 capacitors. Transistor 311 is coupled between the sources of transistors 19-20 and the ground voltage. The gate of transistor 313 and the source and drain of transistor 312 are coupled to the drain of transistor 311 and to the sources of transistors 19-20. The timing circuits 321 and 325, transistors 310-313, inverters 302-304, and logic AND gate 305 form a write assist circuit that assists a write operation to the memory array 301, as described in further detail below.

FIG. 4A is a diagram of an example of a memory circuit 400 that can be used as each of the memory cells in the memory array circuit 101 of FIG. 1 and/or in the memory array circuit 301 of FIG. 3. As various examples, each of the memory cells in the memory array circuits 101 and/or 301 (such as memory cells 21-24, 31-34, and 41-44) includes an instance of the memory circuit 400 shown in FIG. 4A. Memory circuit 400 is a static random access memory (SRAM) circuit that includes 4 n-channel field-effect transistors (FETs) 401-404 and 2 p-channel FETs 405-406. Transistors 403 and 405 are coupled as a first inverter circuit, and transistors 404 and 406 are coupled as a second inverter circuit. These 2 inverter circuits are cross-coupled inverters that are coupled between supply voltage VCC and ground voltage VSS. The gates of transistors 401-402 are coupled to a word line WL. Word line WL may, for example, be any of the word lines that provide word line signals WL0, . . . WLN-2, WLN-1.

A first source/drain of pass transistor 401 is coupled to a non-inverted bit line BL. The second source/drain of pass transistor 401 is coupled to an input of the inverter formed by transistors 404 and 406 and to an output of the inverter formed by transistors 403 and 405. A first source/drain of pass transistor 402 is coupled to an inverted bit line BLb. The second source/drain of transistor 402 is coupled to an output of the inverter formed by transistors 404 and 406 and to an input of the inverter formed by transistors 403 and 405. The bit line BL may, for example, be any of the bit lines that provide non-inverted bit line signals BL0, BL1, BL2, or BL3. The bit line BLb may, for example, be any of the bit lines that provide inverted signals BLb0, BLb 1, BLb2, and BLb3.

FIG. 4B is a diagram of an example of a timing circuit 420 that can be used as each of the timing circuits 321 and 325 in the timing column of timing circuits in memory array circuit 301 of FIG. 3. As an example, each of the timing circuits 321 and 325 in memory array circuit 301 may include an instance of the timing circuit 420 shown in FIG. 4B. In an exemplary implementation, timing circuit 325 includes multiple instances of timing circuit 420 (e.g., 6 timing circuits 420 coupled in parallel). Timing circuit 420 includes 4 n-channel field-effect transistors (FETs) 421-424 and 2 p-channel FETs 425-426. The sources of transistors 423-424 are coupled to receive the ground voltage VSS, and the sources of transistors 425-426 are coupled to receive supply voltage VCC. The gates of transistors 421-422 are coupled to a conductive line REFWL. The conductive line REFWL for each of the timing circuits 420 in timing circuit 325 is coupled to receive the output signal WLDET of WL detect circuit 320. The conductive line REFWL for each of the timing circuits 420/321, including timing circuits 321A and 321B, is coupled to the conductor that transmits the tie low signal TL (e.g., at the ground voltage VSS).

A first source/drain of pass transistor 421 is coupled to the conductive line that provides signal REFBL in memory circuit 300. The second source/drain of pass transistor 421 is coupled to sources of transistors 423 and 425 and to gates of transistors 424 and 426. A first source/drain of pass transistor 422 is coupled to a conductor that provides supply voltage VCC. The second source/drain of pass transistor 422 is coupled to the sources of transistors 424 and 426. The gates of transistors 423 and 425 are coupled to receive supply voltage VCC. Because the conductive lines REFWL in timing circuits 321A, 321B, etc. are coupled to receive signal TL at voltage VSS, transistors 421-422 in timing circuits 321/420 are off. The timing circuits 420 in timing circuits 321A, 321B, etc. are therefore disabled, and only act as loads for signal REFBL so that the discharge time for signal REFBL tracks the discharge time for the bit lines coupled to the memory cells in memory array 301.

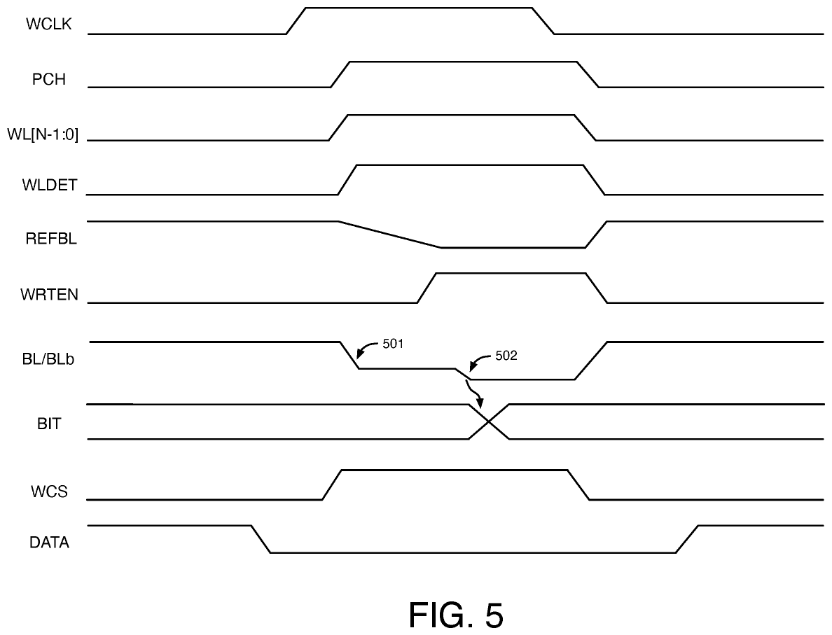

Further details of the operation of memory circuit 300 are now described in the context of FIG. 5. FIG. 5 is a timing diagram that illustrates examples of waveforms for 10 of the signals in memory circuit 300. Initially, the WCLK signal, the PCH signal, the WLDET signal, and the WRTEN signal have low voltages (e.g., the ground voltage). In response to signal PCH having a low voltage, p-channel transistor 310 is on, providing current from supply voltage VCC to signal REFBL. As a result, transistor 310 pre-charges the conductor that provides signal REFBL to supply voltage VCC. Transistor 311 is on in response to the inverted WRTEN signal output by inverter 303 having a high voltage. At the start of a write operation to write one or more bits to the memory cells in memory array 301, the Data input signal transitions from a high voltage (e.g., at supply voltage VCC) to a low voltage or from a low voltage to a high voltage. In the example of FIG. 5, the Data input signal transitions from a high voltage to a low voltage to write a 0 bit to one or more of the memory cells, as described herein with respect to FIG. 1. Then, the write clock signal WCLK transitions from the low voltage to a high voltage. Subsequently, the PCH signal transitions from the low voltage to a high voltage (e.g., voltage VCC) causing transistor 310 to turn off.

In addition, the WL decoder circuits 103 cause the word line signals WL[N-1:0] that are selected based on the address indicated by the row pre-decoder signals RPD to transition from low voltages to high voltages, as shown in FIG. 5. The word line signals that transition to high voltages are transmitted on the word lines coupled to memory cells being written to during the write operation. Also, WCS circuit 104 causes the write control signals WCS for the columns of memory cells in array 301 selected to be written to during the write operation to transition from low voltages to high voltages. In response to the write control signals WCS for the selected columns of memory cells in array 301 transitioning to high voltages, and the Data input signal having a low voltage to write 0 bits to one or more memory cells in each selected column, the inverted bit line signals BLb for the selected columns transition to high voltages, and the non-inverted bit line signals BL for the selected columns transition to low voltages (as shown by arrow 501 in FIG. 5). In response to the write control signals WCS for the selected columns of memory cells in array 301 transitioning to high voltages, and the Data input signal having a high voltage to write 1 bits to one or more memory cells in each selected column, the inverted bit line signals BLb for the selected columns transition to low voltages, and the non-inverted bit line signals BL for the selected columns transition to high voltages.

As shown in FIG. 5, WL detect circuit 320 asserts the WLDET signal from a low voltage to a high voltage in response to the row pre-decoder signals RPD indicating an address transition. In response to the WLDET signal transitioning to a high voltage, transistors 421-422 in timing circuit 325/420 turn on, because conductor REFWL in timing circuit 325 is coupled to receive signal WLDET. When transistor 421 in timing circuit 325/420 is on, current flows from the conductor that transmits signal REFBL through transistors 421 and 423 to the ground voltage VSS. Transistor 423 is on, and transistor 425 is off, because the gates of transistors 423 and 425 are coupled to supply voltage VCC. As previously discussed, the voltage of signal REFBL is initially pre-charged high. After transistor 421 in timing circuit 325/420 turns on, the voltage of signal REFBL discharges to the VSS ground voltage through transistors 421 and 423, as shown in FIG. 5. In response to the voltage of signal REFBL decreasing to the VSS ground voltage, and the WCLK signal having a high voltage, the output signal WRTEN of AND gate 305 transitions to a high voltage, and as a result, inverter circuit 303 turns transistor 311 off, and inverters 304 drive the gate of transistor 312 and the source and drain of transistor 313 to low voltages. The capacitors formed by transistors 312 and 313 then pull the voltage at the sources of transistors 19-20 below the ground voltage VSS, which causes the voltages of the inverted (or non-inverted) bit line signals BL/BLb to decrease below the ground voltage VSS, as shown by arrow 502 in FIG. 5. As a result of these bit line signals being pulled below ground voltage VSS, the write assist circuit of FIG. 3 is able to provide a more robust and faster write operation to the memory cells in the selected columns of memory array 301. FIG. 5 also shows examples of transitions in BIT signals that are stored in the cross-coupled inverters in one of memory cells 400 in array 301 and that occur in response to the voltage transitions in bit line signals BL/BLb.

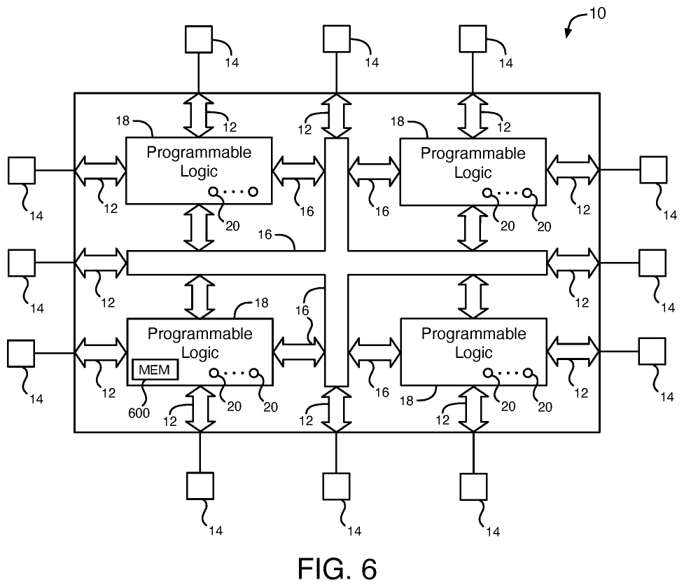

An illustrative programmable logic integrated circuit (IC) 10 that includes a memory circuit 600 is shown in FIG. 6. Memory circuit 100 (FIG. 1) and memory circuit 300 (FIG. 3) are examples of memory circuit 600. Although one memory circuit 600 is shown in FIG. 6, IC 10 may have any suitable number of memory circuits 600. As shown in FIG. 6, programmable logic integrated circuit 10 may have input-output circuitry 12 for driving signals off of IC 10 and for receiving signals from other devices via input-output pads 14. Interconnection resources 16 such as global, regional, and local vertical and horizontal conductive lines and buses may be used to route signals on IC 10. Interconnection resources 16 include fixed interconnects (conductive lines) and programmable interconnects (i.e., programmable connections between respective fixed interconnects). Programmable logic circuitry 18 may include combinational and sequential logic circuitry. The programmable logic circuitry 18 may be configured to perform custom logic functions according to a custom design for IC 10.

Programmable logic IC 10 contains memory elements 20 (e.g., memory cells in memory circuits 100 or 300) that can be loaded with configuration data (also called programming data) using pads 14 and input-output circuitry 12. Once loaded, the memory elements 20 may each provide a corresponding static control output signal that controls the state of an associated logic component in programmable logic circuitry 18. Typically, the memory element output signals are used to control the gates of metal-oxide-semiconductor (MOS) transistors.

In general, software and data for performing any of the functions disclosed herein may be stored in non-transitory computer readable storage media. Non-transitory computer readable storage media is tangible computer readable storage media that stores data for a significant period of time, as opposed to media that only transmits propagating electrical signals (e.g., wires). The software code may sometimes be referred to as software, data, program instructions, instructions, or code. The non-transitory computer readable storage media may include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

Additional examples are now disclosed. Example 1 is a memory circuit comprising: a memory array circuit that comprises a first column of memory cells; a column selection circuit coupled to the first column of the memory cells through a first bit line, wherein the column selection circuit pulls a voltage of the first bit line toward a predefined voltage in response to a first write control signal during a first write operation to at least one of the memory cells in the first column; a write enable circuit that generates a write enable signal; and a first regenerative repeater circuit coupled to the first column of the memory cells through the first bit line, wherein the first regenerative repeater circuit pulls the voltage of the first bit line toward the predefined voltage in response to the write enable signal during the first write operation.

In Example 2, the memory circuit of Example 1 may optionally include, wherein the first regenerative repeater circuit discharges the first bit line to a ground voltage during the first write operation.

In Example 3, the memory circuit of any one of Examples 1-2 may optionally include, wherein the first regenerative repeater circuit comprises a first inverter circuit coupled to the first bit line and a first transistor coupled to the first bit line and to an output of the first inverter circuit, and wherein the first inverter circuit turns the first transistor on to pull the voltage of the first bit line toward the predefined voltage in response to the column selection circuit pulling the voltage of the first bit line toward the predefined voltage during the first write operation.

In Example 4, the memory circuit of any one of Examples 1-3 may optionally include, wherein the first regenerative repeater circuit is coupled to the first column of the memory cells through a second bit line, and wherein the first regenerative repeater circuit pulls the voltage of the second bit line toward the predefined voltage in response to the write enable signal during a second write operation to at least one of the memory cells in the first column.

In Example 5, the memory circuit of any one of Examples 1-4 may further comprise: word line decoder circuits coupled to the memory array circuit, wherein the memory array circuit comprises rows of the memory cells, wherein the word line decoder circuits are coupled to the rows of the memory cells through word lines, and wherein the word line decoder circuits assert selected ones of the word lines to write bits to the memory cells in the rows coupled to the selected ones of the word lines.

In Example 6, the memory circuit of any one of Examples 1-5 may optionally include, wherein the memory array circuit further comprises a second column of memory cells, wherein the column selection circuit is coupled to the second column of the memory cells through a second bit line, wherein the column selection circuit pulls a voltage of the second bit line toward the predefined voltage in response to a second write control signal during a second write operation to at least one of the memory cells in the second column, and wherein the memory circuit further comprises: a second regenerative repeater circuit coupled to the second column of the memory cells through the second bit line, and wherein the second regenerative repeater circuit pulls the voltage of the second bit line toward the predefined voltage in response to the write enable signal during the second write operation.

In Example 7, the memory circuit of any one of Examples 1-6 may optionally include, wherein the column selection circuit is coupled to the first bit line next to a first edge of the memory array circuit, wherein the first regenerative repeater circuit is coupled to the first bit line next to a second edge of the memory array circuit, and wherein the second edge of the memory array circuit is opposite to the first edge.

In Example 8, the memory circuit of any one of Examples 1-2 or 5-7 may optionally include, wherein the first regenerative repeater circuit comprises first and second inverter circuits and first and second transistors, wherein the first transistor and an input of the first inverter circuit are coupled to the first bit line, wherein an output of the first inverter circuit is coupled to an input of the first transistor, wherein the second transistor and an input of the second inverter circuit are coupled to the first column of the memory cells through a second bit line, and wherein an output of the second inverter circuit is coupled to an input of the second transistor.

Example 9 is a memory circuit comprising: a memory array circuit that comprises columns of memory cells coupled to bit lines and a timing circuit coupled to a reference bit line; a column selection circuit coupled to the columns of the memory cells through the bit lines; a write driver circuit coupled to the column selection circuit; and a first capacitor coupled to the write driver circuit, wherein the timing circuit adjusts a voltage of the reference bit line to cause an adjustment to a voltage on the first capacitor during a write operation to at least one of the memory cells, and wherein the write driver circuit and the column selection circuit decrease a voltage of a selected one of the bit lines below a predefined voltage in response to the adjustment to the voltage on the first capacitor.

In Example 10, the memory circuit of Example 9 may optionally include, wherein the write driver circuit selects one of the bit lines as the selected one of the bit lines that is decreased below a ground voltage in response to the adjustment to the voltage on the first capacitor based on a data input signal that indicates a bit value to write to the at least one of the memory cells during the write operation.

In Example 11, the memory circuit of any one of Examples 9-10 may further comprise: a second capacitor coupled to the write driver circuit, wherein the timing circuit adjusts the voltage of the reference bit line to cause an adjustment to a voltage on the second capacitor during the write operation, and wherein the write driver circuit and the column selection circuit decrease the voltage of the selected one of the bit lines below the predefined voltage in response to the adjustments to the voltages on the first and the second capacitors.

In Example 12, the memory circuit of any one of Examples 9-11 may further comprise: logic circuits coupled between the reference bit line and the first capacitor.

In Example 13, the memory circuit of any one of Examples 9-12 may optionally include, wherein the timing circuit comprises first and second transistors, and wherein the first transistor and the second transistor discharge the reference bit line by coupling the reference bit line to a node at a ground voltage during the write operation.

In Example 14, the memory circuit of any one of Examples 9-13 may further comprise: a word line detection circuit that asserts a word line detect signal in response to a change in an address provided to the memory circuit during the write operation, wherein the timing circuit comprises a transistor that turns on in response to the word line detection circuit asserting the word line detect signal to adjust the voltage on the reference bit line during the write operation.

In Example 15, the memory circuit of any one of Examples 9-14 may optionally include, wherein the memory array circuit further comprises transistors coupled to the reference bit line that cause a discharge time for the voltage of the reference bit line to track a discharge time for the selected one of the bit lines during the write operation.

Example 16 is a method for writing data to a memory circuit, the method comprising: driving a voltage of a first bit line toward a predefined voltage with a column selection circuit in response to a first write control signal during a first write operation to a column of memory cells in the memory circuit, wherein the column selection circuit is coupled to the column of the memory cells through the first bit line; generating a write enable signal with a write enable circuit; and driving the voltage of the first bit line toward the predefined voltage with a first regenerative repeater circuit in response to the write enable signal during the first write operation, wherein the first regenerative repeater circuit is coupled to the column of the memory cells through the first bit line.

In Example 17, the method of Example 16 may optionally include, wherein driving the voltage of the first bit line toward the predefined voltage with the first regenerative repeater circuit further comprises: turning on a transistor in the first regenerative repeater circuit using an inverter circuit to drive the voltage of the first bit line toward the predefined voltage in response to the column selection circuit causing the inverter circuit to invert a voltage at a gate of the transistor during the first write operation.

In Example 18, the method of any one of Examples 16-17 may further comprise: driving a voltage of a second bit line toward the predefined voltage with the column selection circuit in response to a second write control signal during a second write operation to the column of the memory cells in the memory circuit, wherein the column selection circuit is coupled to the column of the memory cells through the second bit line; and driving the voltage of the second bit line toward the predefined voltage with a second regenerative repeater circuit in response to the write enable signal during the second write operation, wherein the second regenerative repeater circuit is coupled to the column of the memory cells through the second bit line.

In Example 19, the method of Example 18 may optionally include, wherein driving the voltage of the second bit line toward the predefined voltage with the second regenerative repeater circuit further comprises: turning on a transistor in the second regenerative repeater circuit using an inverter circuit to drive the voltage of the second bit line toward the predefined voltage in response to the column selection circuit causing the inverter circuit to invert a voltage at a gate of the transistor during the second write operation.

In Example 20, the method of any one of Examples 16-19 may optionally include, wherein driving the voltage of the first bit line toward the predefined voltage with the column selection circuit further comprises: driving the voltage of the first bit line toward the predefined voltage with a write driver circuit that receives a data input signal that indicates a bit value to write to at least one of the memory cells in the column of the memory cells during the first write operation, wherein the write driver circuit is coupled to the column selection circuit.

The foregoing description of the exemplary embodiments has been presented for the purpose of illustration. The foregoing description is not intended to be exhaustive or to be limiting to the examples disclosed herein. In some instances, various features can be employed without a corresponding use of other features as set forth. Many modifications, substitutions, and variations are possible in light of the above teachings, without departing from the scope of the present embodiments.

What is claimed is:

1. A memory circuit comprising:
a memory array circuit that comprises a first column of memory cells;
a column selection circuit coupled to the first column of the memory cells through a first bit line, wherein the column selection circuit pulls a voltage of the first bit line toward a predefined voltage in response to a first write control signal during a first write operation to at least one of the memory cells in the first column;
a write enable circuit that generates a write enable signal; and
a first regenerative repeater circuit coupled to the first column of the memory cells through the first bit line, wherein the first regenerative repeater circuit pulls the voltage of the first bit line toward the predefined voltage in response to the write enable signal during the first write operation.

2. The memory circuit of claim 1, wherein the first regenerative repeater circuit discharges the first bit line to a ground voltage during the first write operation.

3. The memory circuit of claim 1, wherein the first regenerative repeater circuit comprises a first inverter circuit coupled to the first bit line and a first transistor coupled to the first bit line and to an output of the first inverter circuit, and wherein the first inverter circuit turns the first transistor on to pull the voltage of the first bit line toward the predefined voltage in response to the column selection circuit pulling the voltage of the first bit line toward the predefined voltage during the first write operation.

4. The memory circuit of claim 1, wherein the first regenerative repeater circuit is coupled to the first column of the memory cells through a second bit line, and wherein the first regenerative repeater circuit pulls a voltage of the second bit line toward the predefined voltage in response to the write enable signal during a second write operation to at least one of the memory cells in the first column.

5. The memory circuit of claim 1 further comprising:
word line decoder circuits coupled to the memory array circuit, wherein the memory array circuit comprises rows of the memory cells, wherein the word line decoder circuits are coupled to the rows of the memory cells through word lines, and wherein the word line decoder circuits assert selected ones of the word lines to write bits to the memory cells in the rows coupled to the selected ones of the word lines.

6. The memory circuit of claim 1, wherein the memory array circuit further comprises a second column of memory cells, wherein the column selection circuit is coupled to the second column of the memory cells through a second bit line, wherein the column selection circuit pulls a voltage of the second bit line toward the predefined voltage in response to a second write control signal during a second write operation to at least one of the memory cells in the second column, and wherein the memory circuit further comprises:
a second regenerative repeater circuit coupled to the second column of the memory cells through the second bit line, wherein the second regenerative repeater circuit pulls the voltage of the second bit line toward the predefined voltage in response to the write enable signal during the second write operation.

7. The memory circuit of claim 1, wherein the column selection circuit is coupled to the first bit line next to a first edge of the memory array circuit, wherein the first regenerative repeater circuit is coupled to the first bit line next to a second edge of the memory array circuit, and wherein the second edge of the memory array circuit is opposite to the first edge.

8. The memory circuit of claim 1, wherein the first regenerative repeater circuit comprises first and second inverter circuits and first and second transistors, wherein the first transistor and an input of the first inverter circuit are coupled to the first bit line, wherein an output of the first inverter circuit is coupled to an input of the first transistor, wherein the second transistor and an input of the second inverter circuit are coupled to the first column of the memory cells through a second bit line, and wherein an output of the second inverter circuit is coupled to an input of the second transistor.

9. A memory circuit comprising:
a memory array circuit that comprises columns of memory cells coupled to bit lines and a timing circuit coupled to a reference bit line;
a column selection circuit coupled to the columns of the memory cells through the bit lines;
a write driver circuit coupled to the column selection circuit; and
a first capacitor coupled to the write driver circuit, wherein the timing circuit adjusts a voltage of the reference bit line to cause an adjustment to a voltage on the first capacitor during a write operation to at least one of the memory cells, and wherein the write driver circuit and the column selection circuit decrease a voltage of a selected one of the bit lines below a predefined voltage in response to the adjustment to the voltage on the first capacitor.

10. The memory circuit of claim 9, wherein the write driver circuit selects one of the bit lines as the selected one of the bit lines that is decreased below a ground voltage in response to the adjustment to the voltage on the first capacitor based on a data input signal that indicates a bit value to write to the at least one of the memory cells during the write operation.

11. The memory circuit of claim 9 further comprising:
a second capacitor coupled to the write driver circuit, wherein the timing circuit adjusts the voltage of the reference bit line to cause an adjustment to a voltage on the second capacitor during the write operation, and wherein the write driver circuit and the column selection circuit decrease the voltage of the selected one of the bit lines below the predefined voltage in response to the adjustments to the voltages on the first and the second capacitors.

12. The memory circuit of claim 9 further comprising:
logic circuits coupled between the reference bit line and the first capacitor.

13. The memory circuit of claim 9, wherein the timing circuit comprises first and second transistors, and wherein the first transistor and the second transistor discharge the reference bit line by coupling the reference bit line to a node at a ground voltage during the write operation.

14. The memory circuit of claim 9 further comprising:
a word line detection circuit that asserts a word line detect signal in response to a change in an address provided to the memory circuit during the write operation, wherein the timing circuit comprises a transistor that turns on in response to the word line detection circuit asserting the word line detect signal to adjust the voltage on the reference bit line during the write operation.

15. The memory circuit of claim 9, wherein the memory array circuit further comprises transistors coupled to the reference bit line that cause a discharge time for the voltage of the reference bit line to track a discharge time for the selected one of the bit lines during the write operation.

16. A method for writing data to a memory circuit, the method comprising:
driving a voltage of a first bit line toward a predefined voltage with a column selection circuit in response to a first write control signal during a first write operation to a column of memory cells in the memory circuit, wherein the column selection circuit is coupled to the column of the memory cells through the first bit line;
generating a write enable signal with a write enable circuit; and
driving the voltage of the first bit line toward the predefined voltage with a first regenerative repeater circuit in response to the write enable signal during the first write operation, wherein the first regenerative repeater circuit is coupled to the column of the memory cells through the first bit line.

17. The method of claim 16, wherein driving the voltage of the first bit line toward the predefined voltage with the first regenerative repeater circuit further comprises:
turning on a transistor in the first regenerative repeater circuit using an inverter circuit to drive the voltage of the first bit line toward the predefined voltage in response to the column selection circuit causing the inverter circuit to invert a voltage at a gate of the transistor during the first write operation.

18. The method of claim 16 further comprising:
driving a voltage of a second bit line toward the predefined voltage with the column selection circuit in response to a second write control signal during a second write operation to the column of the memory cells in the memory circuit, wherein the column selection circuit is coupled to the column of the memory cells through the second bit line; and
driving the voltage of the second bit line toward the predefined voltage with a second regenerative repeater circuit in response to the write enable signal during the second write operation, wherein the second regenerative repeater circuit is coupled to the column of the memory cells through the second bit line.

19. The method of claim 18, wherein driving the voltage of the second bit line toward the predefined voltage with the second regenerative repeater circuit further comprises:
turning on a transistor in the second regenerative repeater circuit using an inverter circuit to drive the voltage of the second bit line toward the predefined voltage in response to the column selection circuit causing the inverter circuit to invert a voltage at a gate of the transistor during the second write operation.

20. The method of claim 16, wherein driving the voltage of the first bit line toward the predefined voltage with the column selection circuit further comprises:
driving the voltage of the first bit line toward the predefined voltage with a write driver circuit that receives a data input signal that indicates a bit value to write to at least one of the memory cells in the column of the memory cells during the first write operation, wherein the write driver circuit is coupled to the column selection circuit.
